(19) United States
(12) Patent Application Publication
(10) Pub. No.: US 2010/0265732 A1
(43) Pub. Date: Oct. 21, 2010

(54) Light tube with led light source

(76) Inventor: Zi Hui Liu, Guangzhou City (CN)

Correspondence Address: Scihead PTO, Room 1508 Hui-Hua Commercial Trading Building, No.80, Shen-Lei Chung Rd., Guangzhou City, Guang Dong Province, 510070, CN

(21) Appl. No.: 12/385,821

(22) Filed: Apr. 21, 2009

(51) Int. Cl. H01L 33/00

(52) U.S. Cl. 362/555

(57) ABSTRACT

A light tube with an LED light source includes a casing, a control circuit board, an LED circuit board inside the casing, and LEDs coupled to the LED circuit board. Input and output ports of the control circuit board are connected to pins of the casing via an input line and to the LED circuit board via an output line, respectively. A power module and a control module are provided on the control circuit board and at input and output ends thereof, respectively. The power module includes first and second filter capacitors and a rectifier bridge circuit. The first and second filter capacitors straddle and connect with input and output ends of the rectifier bridge circuit, respectively. The output end of the rectifier bridge circuit connects with the control module. Thereby, high-frequency AC from an electronic ballast or low-frequency AC is converted to DC for the LEDs.

### BACKGROUND OF THE INVENTION

1. Technical Field

The present invention relates lighting devices and, more particularly, to a light tube with an LED light source.

2. Description of Related Art

Owing to advancement of LED technology, there is a trend for products to be lit by LEDs rather than conventional light sources. For example, light tubes with an LED light source are increasingly replacing conventional fluorescent lamps. However, existing light tubes with an LED light source (hereinafter referred to as LED light tubes) can only convert low-frequency, say, 50-60 Hz, alternating current (AC) to direct current (DC) but cannot convert high-frequency alternating current outputted by an electronic ballast to direct current to be supplied to LEDs.

Hence, no existing LED light tubes can be directly installed on a fluorescent lamp holder equipped with an electronic ballast. Normally, the electronic ballast is removed from the fluorescent lamp holder before an LED light tube is installed thereon, which brings inconvenience to users and hinders the promotion of energy-saving and environment-friendly light sources.

### BRIEF SUMMARY OF THE INVENTION

It is a primary objective of the prevent invention to provide a light tube with an LED light source such that the light tube converts low-frequency alternating current to direct current or converts high-frequency alternating current outputted by an electronic ballast to direct current to be used as the operating current for the light tube with an LED light source.

To achieve the above and other objectives, the present invention provides a light tube with an LED light source, wherein the light tube comprises LEDs, a casing, a control circuit board, and an LED circuit board. The LEDs are fixed in position to the LED circuit board inside the casing. An input port of the control circuit board is connected to pins at two ends of the casing via an input line. An output port of the control circuit board is connected to the LED circuit board via an output line. A power module and a control module are provided on the control circuit board. The power module is positioned at an input end of the control circuit board. The control module is positioned at an output end of the control circuit board. The power module includes a first filter capacitor, a rectifier bridge circuit, and a second filter capacitor. The first filter capacitor straddles and connects with an input end of the rectifier bridge circuit. The second filter capacitor straddles and connects with an output end of the rectifier bridge circuit. The output end of the rectifier bridge circuit connects with the control module. The rectifier bridge circuit comprises four diodes.

Unlike the prior art, the present invention discloses converting low-frequency alternating current to direct current or converting high-frequency alternating current outputted by an electronic ballast to direct current to be supplied to LEDs, thereby allowing the light tube with an LED light source of the present invention to be directly installed not only on a fluorescent lamp holder without a ballast or with an inductive ballast, but also on a fluorescent lamp holder equipped with an electronic ballast. Hence, the light tube with an LED light source of the present invention is a good substitute for conventional fluorescent lamps in whatever conditions.

### BRIEF DESCRIPTION OF THE SEVERAL VIEWS OF THE DRAWINGS

The invention as well as a preferred mode of use, further objectives, and advantages thereof will be best understood by referring to the following detailed description of a preferred embodiment in conjunction with the accompanying drawings, wherein:

FIG. 1 is a partial cross-sectional view of the present invention;

FIG. 2 is another partial cross-sectional view of the present invention;

FIG. 3 is yet another partial cross-sectional view of the present invention; and

FIG. 4 shows a circuit of the present invention.

### DETAILED DESCRIPTION OF THE INVENTION

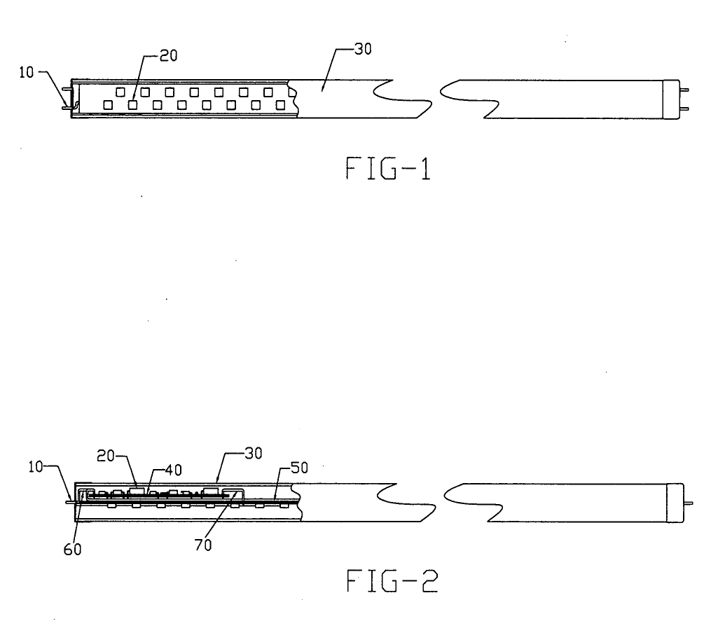

Referring to FIGS. 1 and 2, the present invention discloses a light tube with an LED light source (hereinafter referred to as an LED light tube). The light tube (LED light tube) comprises a casing 30 penetrable by light. The casing 30 has two ends each provided with a pin 10 functioning as a current contact. The light tube (LED light tube) further comprises an LED circuit board 50 and a control circuit board 40, both provided inside the casing 30. An input port of the control circuit board 40 is connected to the pins 10 at the two ends of the casing 30 via an input line 60. An output port of the control circuit board 40 is connected to the LED circuit board 50 via an output line 70.

The light tube (LED light tube) further comprises a plurality of LEDs 20 provided on and fixed in position to the LED circuit board 50 by soldering. The number of the LEDs 20 is an even number 2n, where n denotes an integer. Light emitted by each of the LEDs 20 penetrates the casing 30.

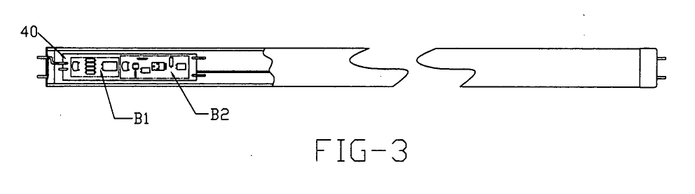

Referring to FIG. 3, a power module B1 and a control module B2 are provided on the control circuit board 40. The power module B1 is positioned at an input end of the control circuit board 40. The control module B2 is positioned at an output end of the control circuit board 40.

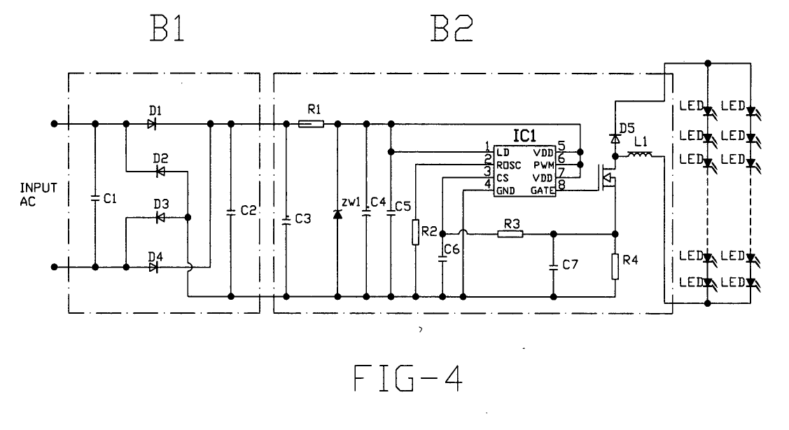

Referring to FIG. 4, the power module B1 comprises a first filter capacitor C1, a second filter capacitor C2, and a rectifier bridge circuit including diodes D1, D2, D3, and D4. The first and second filter capacitors C1, C2 connect with input and output ends of the rectifier bridge circuit, respectively. The control module B2 connects with the output end of the rectifier bridge circuit. The control module B2 comprises an IC1; capacitors C3, C4, C5, C6, C7; resistors R1, R2, R3, R4; a voltage regulator tube ZW1; a diode D5; and an inductor L1.

Given the above circuit layout, when power is ON, the first filter capacitor C1 of the power module B1 on the control circuit board 40 processes input alternating current such that non-sinusoidal high-frequency alternating current outputted by an electronic ballast (not shown) is filtered and turned into readily rectifiable alternating current. The alternating current which has been filtered by the first filter capacitor C1 is then rectified by the rectifier bridge circuit including the diodes D1, D2, D3, and D4 so as to be converted to direct current. Afterward, the second filter capacitor C2 filters the direct current to remove noise therefrom, and the resultant noise-free direct current is supplied to the IC1 of the control module B2 and the LEDs 20 in the LED light tube. Also, the control module B2 controls current inputted to the LEDs 20 to be within a normal operating range so that the LEDs 20 emit light.

As revealed by the above description, once the LED light tube is installed on a fluorescent lamp holder, connected to electrodes, and powered on, the power module B1 can convert alternating current, whether ordinary alternating current or high-frequency alternating current outputted by an electronic ballast, to direct current to be supplied to the LEDs 20, thereby markedly increasing the applicability of the LED light tube and widening the use thereof.

In addition, the LED light tube disclosed in the present invention is highly efficient and has a long service life. A good substitute for conventional fluorescent lamps, the LED light tube of the present invention is effective in saving energy and reducing the number of times of diode replacement, as well as preventing pollution and waste of resources which might otherwise arise from the disposal of waste fluorescent lamps.

1. A light tube with an LED light source, comprising:
a casing penetrable by light;
an LED circuit board provided inside the casing;
a plurality of LEDs provided on the LED circuit board; and
a control circuit board provided inside the casing and electrically coupled to the LED circuit board;
wherein said control circuit board has a power module and electrically coupled to a control module, the power module being configured for rectification, and the control module being configured to control a range of current.

2. The light tube of claim 1, further comprising two pins provided at two ends of the casing, respectively, and electrically connected to the control circuit board via an input line.

3. The light tube of claim 1, wherein the power module comprises a first filter capacitor, a rectifier bridge circuit, and a second filter capacitor, the first filter capacitor being positioned at an input end of the rectifier bridge circuit, the second filter capacitor being positioned at an output end of the rectifier bridge circuit, and the output end of the rectifier bridge circuit being connected to the control module.

4. The light tube of claim 3, wherein the rectifier bridge circuit comprises four diodes.
